(19) United States
(12) Patent Application Publication
(10) Pub. No.: US 2025/0048581 A1
(43) Pub. Date: Feb. 6, 2025

(54) RISER CAGE BRACKET ASSEMBLED FROM A RISER CAGE BODY AND INTERCHANGEABLE RISER CAGE WINDOWS

(71) Applicant: HEWLETT PACKARD ENTERPRISE DEVELOPMENT LP, Spring, TX (US)

(72) Inventors: Peng ChiangHsieh, Taipei (TW); Yi-Lung Chou, Taipei (TW); Chi-Ting Yang, Taipei (TW)

(21) Appl. No.: 18/363,969

(22) Filed: Aug. 2, 2023

(51) Int. Cl. H05K 7/14

(52) U.S. Cl. CPC H05K 7/1489

(57) ABSTRACT

A system for assembling a riser cage bracket is disclosed. The system includes a riser cage body, a first riser cage window, and a second riser cage window. The first and second riser cage windows are configured to be interchangeably and removably connectable to the riser cage body to assemble the riser cage bracket. The first riser cage window is configured to, when connected to the riser cage body, define a first space between the riser cage body and the first riser cage window to receive a full-height expansion card detachably coupled to the riser cage bracket. The second riser cage window is configured to, when connected to the riser cage body, define a second space between the riser cage body and the second riser cage window to receive a low-profile expansion card detachably coupled to the riser cage bracket.

### BACKGROUND

An electronic device such as a computer, a networking device, or the like may include a primary system board (e.g., a motherboard) having hardware components such as central processor units, resistors, capacitors, or the like to provide some basic function. In order to pursue stronger performance and/or expand functionality of the electronic device, additional hardware components such as an expansion card may be detachably coupled to the primary system board. Expansion cards may come in a variety of sizes and form factors, including, for example, a full-height expansion card and a low-profile expansion card.

In some electronic devices, the primary system board may include an electrical connector that can directly receive the expansion card. However, in other electronic devices, the primary system board may lack the appropriate number or type of electrical connectors needed to receive desired expansion card(s), or the electrical connectors may be present but in an inconvenient location or orientation, and thus in such electronic devices, another card (or intermediary card) which carries an electrical connector that is suitable for the expansion card may be detachably coupled to the primary system board, thus providing the needed connection point for the expansion card. Such an intermediary card is generally referred to as a riser card.

Additionally, a riser cage bracket may be provided to support the riser card. The riser cage bracket may additionally secure and support the expansion card when the expansion card is disposed in the riser cage bracket and detachably coupled to the riser card. Multiple different types of riser cage brackets, each having different dimensions, exist to support the various different form factors of expansion cards, such as, for example, a full-height riser cage bracket to secure and support a full-height expansion card and a low-profile riser cage bracket to secure and support a low-profile expansion card.

### BRIEF DESCRIPTION OF THE DRAWINGS

Various examples will be described below with reference to the following figures.

FIG. 1A illustrates a block diagram of a system for assembling a riser cage assembly according to an example of the present disclosure.

FIG. 1B illustrates a block diagram of an example riser cage assembly assembled from the system of FIG. 1A according to an example of the present disclosure.

FIG. 1C illustrates a block diagram of another example riser cage assembly assembled from the system of FIG. 1A according to an example of the present disclosure.

FIG. 2 illustrates a perspective view of a riser cage body according to an example of the present disclosure.

FIG. 3 illustrates a perspective view of a riser cage window having a full-height configuration according to an example of the present disclosure.

FIG. 4 illustrates a perspective view of a riser cage bracket having the riser cage body of FIG. 2 and the riser cage window of FIG. 3 according to an example of the present disclosure.

FIG. 5 illustrates an exploded perspective view of a riser cage assembly having the riser cage bracket of FIG. 4, a riser card, and a full-height expansion card according to an example of the present disclosure.

FIG. 6 illustrates an assembled perspective view of the riser cage assembly of FIG. 5 according to an example of the present disclosure.

FIG. 7 illustrates a perspective view of another riser cage window having a low-profile configuration according to an example of the present disclosure.

FIG. 8 illustrates a perspective view of another riser cage bracket having the riser cage body of FIG. 2 and the other riser cage window of FIG. 7 according to an example of the present disclosure.

FIG. 9 illustrates an exploded perspective view of another riser cage assembly having the other riser cage bracket of FIG. 8, a riser card, and a low-profile expansion card according to an example of the present disclosure.

FIG. 10 illustrates an assembled perspective view of the other riser cage assembly of FIG. 9 according to an example of the present disclosure.

FIG. 11 illustrates an exploded perspective view of an electronic device having the riser cage assembly of FIG. 6 according to an example of the present disclosure.

FIG. 12 illustrates an exploded perspective view of another electronic device having the other riser cage assembly of FIG. 10 according to an example of the present disclosure.

FIG. 13 is a flowchart depicting a method of assembling a riser cage bracket according to one example of the present disclosure.

FIG. 14 is a flowchart depicting a method of uninstalling a riser cage assembly in a first configuration from an electronic device, reconfiguring the riser cage assembly from the first configuration to a second configuration, and installing the riser cage assembly in the second configuration to the electronic device according to one example of the present disclosure.

### DETAILED DESCRIPTION

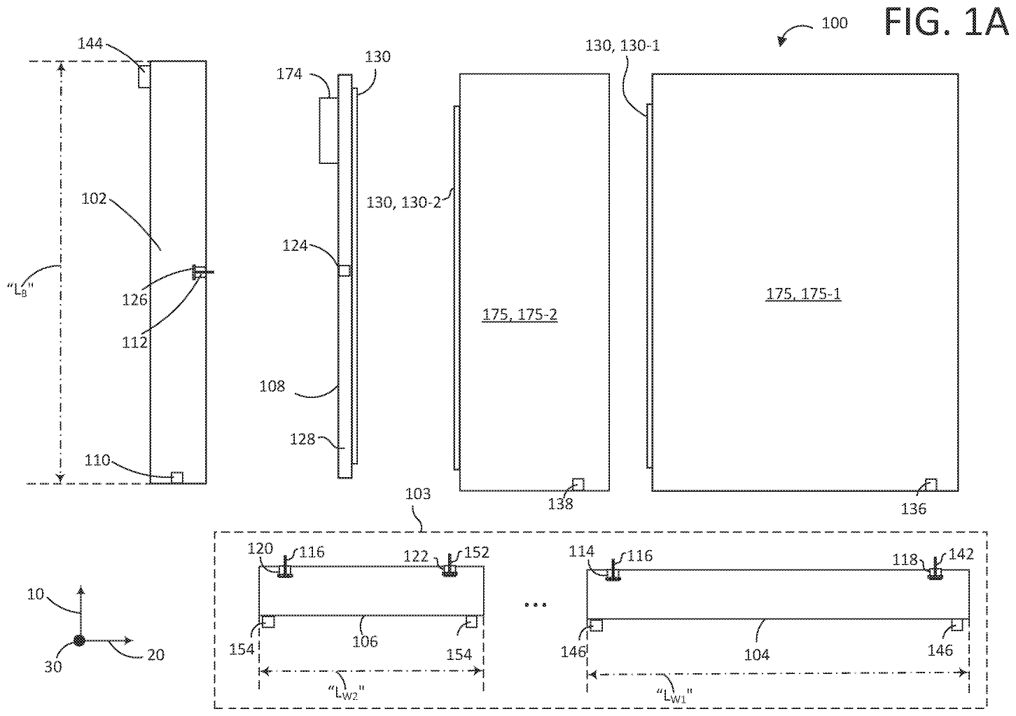

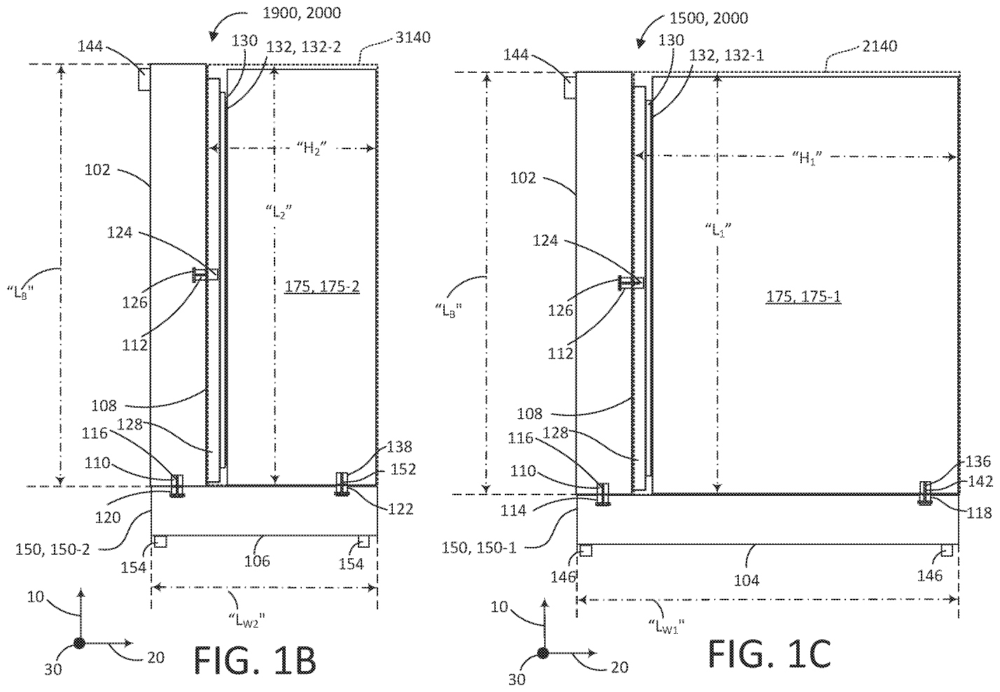

The following detailed description refers to the accompanying drawings. For purposes of explanation, certain examples are described with reference to the components illustrated in FIGS. 1-14. The functionality of the illustrated components may overlap, however, and may be present in a fewer or greater number of elements and components. Moreover, the disclosed examples may be implemented in various environments and are not limited to the illustrated examples. Wherever possible, the same reference numbers are used in the drawings and the following description to refer to the same or similar parts. It is to be expressly understood, however, that the drawings are for the purpose of illustration and description only. While several examples are described in this document, modifications, adaptations, and other implementations are possible. Accordingly, the following detailed description does not limit the disclosed examples. Instead, the proper scope of the disclosed examples may be defined by the appended claims.

As used herein, “riser card” refers to an electronic card having a circuit board and a connector, the circuit board being configured to be coupled to a primary system board (e.g., motherboard) of an electronic device and the connector being configured to removably receive a corresponding connector of an expansion card such that the expansion card is electrically connected to the primary system board via the riser card. As used herein, “expansion card” refers to another electronic card having a circuit board and an electrical connector (e.g., an electrical plug or socket) that can be engaged with (e.g., inserted into) the connector (e.g., an electrical connector) of a riser card, or a connector (e.g., expansion slot) on an electronic device's primary system board to add and/or expand functionality of the electronic device. As used herein, “riser cage bracket” refers to a supporting element that can be configured to support the riser card and install in the electronic device.

A riser cage assembly including a riser cage bracket and a riser card may allow inclusion of additional hardware components such as an expansion card (e.g., display card, graphics processing unit (GPU), accelerator module, networking interface module (NIC), etc.) in an electronic device to improve performance or expand functionality of the electronic device. For example, the riser card is first coupled to the riser cage bracket to form the riser cage assembly, and such riser cage assembly is later installed in the electronic device (e.g., the riser cage bracket may be coupled to a chassis of the electronic device) such that the riser card is detachably coupled to a primary system board of the electronic device. The expansion card is later installed in the riser cage bracket which may further secure and support the expansion card. As the expansion card is installed in the riser cage bracket, an electrical connector of the expansion card is detachably coupled to a connector (e.g., an electrical connector) of the riser card, and thus the expansion card is electrically connected to the primary system board via the riser card. Thus, when the expansion card is detachably coupled to the riser card, electrical signals from the expansion card may be transferred to the primary system board via the riser card. This may allow a type of connector that the primary system board lacks to be added, or the number of such connectors to be expanded, or the locations of such connectors to be repositioned to somewhere more convenient place.

The expansion cards generally have different form factors, e.g., a full-height full-length (“FHFL”) or a half-height full-length (“HHFL”). It may be noted that the expansion card having the “FHFL” form factor may be referred to as a full-height expansion card, and the expansion card having the “HHFL” form factor may be referred to as a low-profile expansion card. Therefore, the riser cage assembly provided to secure and support the expansion card may also need to have different configurations, e.g., a full-height configuration associated with the full-height expansion card, or a low-profile configuration associated with the low-profile expansion card to properly secure and support the expansion card having a corresponding form factor. In other words, a first riser cage assembly having the full-height configuration may be required to secure and support the full-height expansion card and a second riser cage assembly having the low-profile configuration may be required to secure and support the low-profile expansion card. Accordingly, when the electronic device including an expansion card having a first form factor needs to be switched over to a new expansion card having a second form factor, then a pre-installed riser cage assembly configured to secure and support the expansion card having the first form factor has to be replaced with a new riser cage assembly to secure and support the new expansion card having the second form factor. For example, if the pre-installed riser cage assembly having the full-height configuration is installed in the electronic device to secure and support the full-height expansion card, and later there is a requirement to replace the full-height expansion card with the low-profile expansion card, then the pre-installed riser cage assembly may also have to be replaced with the new riser cage assembly having the low-profile configuration to secure and support the low-profile expansion card. Hence, replacing the expansion card with the new expansion card may be cumbersome, time consuming, expensive, and depend on the availability of inventory of such new compatible riser cage bracket. In addition, multiple different types of riser cage brackets may need to be produced, and this may result in additional SKUs being needed and different inventory to be maintained, which can in turn increase costs.

Additionally, when a riser cage assembly is removed (e.g., for replacement), the riser card thereof may need to be disconnected from the primary system board, and similarly when a new riser cage assembly is installed the riser card thereof may need to be connected to the primary system board. However, each such act of disconnecting or connecting a riser card to the primary system board has the potential to cause damage to the electrical connectors of the riser card or of the primary system board. Thus, changing riser cage assemblies (e.g., to change the form factor of expansion cards) can carry a risk of causing damage.

Furthermore, in some cases replacing a riser card assembly with a new riser card assembly may include reusing the same riser card from the old riser card assembly in the new riser card assembly. In other words, in such examples, when the pre-installed riser cage assembly is removed (e.g., to replaced it with the new riser cage assembly), a riser card which is coupled to the pre-installed riser cage bracket of the pre-installed riser cage assembly may be detached from the pre-installed riser cage bracket (after the assembly has been removed from the primary system board) and then the removed riser card may be attached to in the new riser cage bracket to form a new riser cage assembly, which is subsequently installed in the electronic device. Detaching the riser card from the previous riser cage bracket and then attaching the riser card to the new riser cage bracket takes additional time and effort, and therefore in these examples the overall process of replacing the pre-installed riser cage assembly may be even more cumbersome and time consuming. In addition, detaching and attaching the riser card to/from a riser cage bracket has the potential to cause damage to the riser card (e.g., the card may be cracked due to over-torquing of screws).

A technical solution to the aforementioned problems may include providing a riser cage assembly that is reconfigurable into multiple configurations that are compatible with multiple different form factors of expansion cards, and moreover which is capable of remaining connected (at least in part) to the primary system board while being reconfigured. More specifically, the reconfigurable riser cage assembly includes a reconfigurable riser cage bracket which has a riser cage body (to which the riser card is attached) and a riser cage window removably coupled to the riser cage body, with the riser cage window being one of a set of multiple different windows which are interchangeably connectable to the riser cage body. Thus, the riser cage bracket can be reconfigured to have different dimensions (e.g., to accommodate a different expansion card) by disconnecting the currently connected riser cage window from the riser cage body and then connecting another one of the interchangeable riser cage windows to the riser cage body. Consequently, reconfiguring the riser cage assembly does not require replacing the riser cage body (which is common to all configurations of the riser cage assembly), and thus during a process of reconfiguring the riser cage assembly the riser cage body can remain connected to the primary system board, and hence the riser card attached to the riser cage body can also remain connected to the primary system board. Therefore, it can be much easier to replace an expansion card in a system that utilizes the example riser cage assemblies disclosed herein and there is less risk of such replacement causing damage, as compared to the other approaches described above that utilize a monolithic riser cage bracket, at least because in examples disclosed herein there is no need to disconnect and reconnect the riser card from the primary system board or to detach and reattach the riser card to different riser cage brackets.

In examples disclosed herein, a given configuration of the riser cage bracket that is compatible with a given form factor of expansion card may be formed by i) selecting a riser cage window, out of the multiple interchangeable riser cage windows, that corresponds to (e.g., has a dimension commensurate with) the given form factor of expansion card and ii) assembling such selected riser cage window to the common riser cage body. Moreover, the riser cage assembly can be changed to accommodate different form factors of expansion cards by changing which riser cage window is used, but without needing to replace an entire pre-installed riser cage bracket. For example, a first riser cage window having a full-height may be selected for a full-height expansion card, and detachably coupled to the riser cage body to form a first riser cage bracket having a full-height configuration to support and secure the full-height expansion card. Similarly, a second riser cage window having a half-height may be selected for a low-profile expansion card and detachably coupled to the riser cage body to form a second riser cage bracket having a low-profile configuration to support and secure the low-profile expansion card. In particular, the riser cage body may be retained as-is and the first and second riser cage windows may be interchangeably selected depending on the compatibility with the expansion card, and removably connected to the riser cage body to form the first riser cage bracket or the second riser cage bracket. Since the riser cage body is retained and only the riser cage windows are interchanged to assemble the new riser cage bracket that is compatible with the expansion card, such new riser cage bracket provides flexibility, upgradability, serviceability, and benefits from supply chain in terms of reducing number of ready-made riser cage brackets needed in the inventory. Further, since a riser card along with the riser cage body are retained while assembling the new riser cage bracket from the selected riser cage window, a need to remove and reinstall the riser card as in the case of a pre-installed riser cage bracket to form the new riser cage bracket can be avoided. Thus, overcoming the cumbersome and time consuming process associated with removal and reinstallation of the riser card, and also preventing damage or cracks caused to the riser card during such removing and reinstalling process.

In some examples, when the first riser cage window is connected to the riser cage body, a length dimension of the first riser cage window and a length dimension of the riser cage body extends perpendicular to each other, thus forming a generally L-shaped structure defining a space in which a first expansion card can be received. Similarly, when the second riser cage window is connected to the riser cage body, a length dimension of the second riser cage window and the length dimension of the riser cage body extends perpendicular to each other, also forming a generally L-shaped structure defining a space in which a second expansion card can be received. In some examples, the riser cage body may include a coupling portion which may engage with one or more fasteners to interchangeably connect with the first riser cage window and the second riser cage window. Further, each of the first riser cage window and the second riser cage window may have different lengths along their respective length (longitudinal) dimensions.

In some examples, a system (or kit) for assembling a riser cage bracket is disclosed. In such examples, the system includes a riser cage body, a first riser cage window, and a second riser cage window. The first and second riser cage windows are configured to be interchangeably and removably connectable to the riser cage body to assemble the riser cage bracket. For example, the first riser cage window is configured to, when connected to the riser cage body, define a first space between the riser cage body and the first riser cage window to receive a full-height expansion card detachably coupled to the riser cage bracket. Similarly, the second riser cage window is configured to, when connected to the riser cage body, define a second space between the riser cage body and the second riser cage window to receive a low-profile expansion card detachably coupled to the riser cage bracket. In such examples, each of the first space and the second space has dimensions defined by the riser cage body and a corresponding riser cage window among the first riser cage window and the second riser cage window. Specifically, respective length dimensions of the first and second spaces may be defined by the length of the riser cage body, respective width dimensions of the first and second spaces may be defined by a width of the riser cage body and/or a width of the first and second riser cage windows, and respective height dimensions of the first and second spaces may be defined respective lengths of the first and second riser cage windows. Thus, the first space and the second space may have equal lengths, equal widths, and different heights.

In some examples, the riser card is coupled to the riser cage body. The riser card is further detachably coupled to an electronic device and interchangeably detachably coupled to the full-height expansion card and the low-profile expansion card. In particular, the riser card includes a first electrical connector which is interchangeably detachably coupled to the full-height expansion card and the low-profile expansion card. The riser card further includes a second electrical connector which is detachably coupled to a primary system board of the electronic device to establish an electrical connection between the primary system board and the full-height expansion card or the low-profile expansion card through the riser card. In certain examples, the riser card is a peripheral component interconnect express (PCI-e) card. Similarly, each of the full-height expansion card and the low-profile expansion card is a PCI-e expansion card.

Since a new riser cage bracket may be easily assembled by interchangeably and removably connecting one of a multiple types of riser cage windows onto a common riser cage body to form the new riser cage bracket that is compatible with a particular type of expansion card, the new riser cage bracket provides flexibility, serviceability, and benefit from supply chain in terms of reducing number of ready-made riser cage brackets needed in the inventory. Further, the new riser cage bracket is inexpensive to assemble, maintain, and replace, since the riser cage body and a riser board of the pre-installed riser cage bracket are retained, and only the riser cage window that is incompatible with the expansion card is replaced with the riser cage window that is compatible with the expansion card to assemble the new riser cage bracket.

Referring to the Figures, FIG. 1A depicts a block diagram of a system 100 for assembling a riser cage bracket 150 and/or riser cage assembly 2000 comprising the riser cage bracket 150. FIGS. 1B and 1C illustrate two example riser cage assemblies 2000, including two example riser cage brackets 150, assembled from the system 100. It should be understood that FIGS. 1A-1C are not intended to illustrate specific shapes, dimensions, or other structural details accurately or to scale, and that implementations of the system 100, riser cage brackets 150, and riser cage assemblies 2000, may have different numbers and arrangements of the illustrated components and may also include other parts that are not illustrated. The system 100 may function as an inventory of components that may be required for assembling the riser cage bracket 150.

In some examples, the system 100 includes components such as a riser cage body 102 and a set of mutually different riser cage windows 103 that are interchangeably and removably connectable to the riser cage body 102. The set of riser cage window 103 may include at least a first riser cage window 104 and a second riser cage window 106. The riser cage body 102 may be removably coupled to one of the riser cage windows 103 to form a riser cage bracket 150, with the riser cage bracket 150 being capable of taking on multiple different configurations depending on which one of the riser cage windows 103 is coupled to the riser cage body 102. For example, FIGS. 1B and 1C illustrates two example configurations of the riser cage bracket 150, i.e., a first configuration in the form of a first riser cage bracket 150-1 which includes the first riser cage window 104 removably coupled to the riser cage body 102, and a second configuration in the form of a second riser cage bracket 150-2 including the second riser cage window 106 removably coupled to the riser cage body 102. The riser cage bracket 150 is also capable of reconfiguration between these different configurations. For example, the riser bracket 150 can be reconfigured from the configuration of the first riser cage bracket 150-1 to the configuration of the second riser cage bracket 150-2 by removing the first riser cage window 104 and replacing it with the second riser cage window 106. Below, the description will focus on the first and second riser cage brackets 150-1 and 150-2 as two illustrative examples, but it should be understood that the riser bracket 150 may be capable of additional configurations, such as those formed by using other riser cage windows 103. Additional details of these components are described in greater detail below.

Further, in some examples, the system 100 includes a riser card 108, which can be coupled to the riser cage bracket 150 (specifically, to the riser cage body 102). The combination of riser cage bracket 150 and riser card 108, when assembled together, form a riser cage assembly 2000. For example, FIGS. 1B and 1C illustrates two example configurations of the riser cage assembly 2000, i.e., a first configuration in the form of a first riser cage assembly 1500 which includes the first riser cage bracket 150-1 coupled to riser card 108, and a second configuration in the form of a second riser cage assembly 1900 including the second riser cage bracket 150-2 coupled to riser card 108. The riser cage assembly 2000 is also capable of reconfiguration between these different configurations. For example, the riser cage assembly 2000 can be reconfigured from the configuration of the first riser cage assembly 1500 to the configuration of the second riser cage assembly 1900 by removing the first riser cage window 104 and replacing it with the second riser cage window 106. Additional details of these components are described in greater detail below.

In some examples, the system further includes expansion cards 175, which can be removably installed in the riser cage assembly 2000, via removably coupling to the riser card 108.

The riser cage body 102 is a main structural support component of the riser cage bracket 150. The riser cage body 102 has a length dimension “L_{B}” extending along a first direction 10. The length dimension “L_{B}” of the riser cage body 102 may be associated with a full length configuration or a full-length of the expansion card 175 such as a first expansion card 175-1 or a second expansion card 175-2. The riser cage body 102 includes coupling portions (e.g., a first coupling portion 110) to enable the riser cage body 102 to be interchangeably connected with the first riser cage window 104 and the second riser cage window 106. In some examples, the riser cage body 102 is configured to provide support to the riser card 108. For example, the riser cage body 102 includes a second coupling portion 112 to enable the riser cage body 102 to be coupled to the riser card 108.

As noted above, the system includes a set of multiple riser cage windows 103. Each of the riser cage windows 103 is a secondary structural support component of the riser cage bracket 150. Two example riser cage windows, i.e., first riser cage window 104 and second riser cage window 106 are described below for ease of illustration, but in examples additional riser cage windows 103 may be included in the set of riser cage windows 103. In some examples, each riser cage window in the set of riser cage windows 103 has a different length along at least one dimension thereof (e.g., the length or longitudinal dimension thereof), and may correspond to a different form factor of expansion card 175.

For example, the first riser cage window 104 has a length dimension “L_{W1}” extending along a second direction 20. The length dimension “L_{W1}” of the first riser cage window 104 may be associated with a full-height configuration or a full-height of the expansion card 175 such as the first expansion card 175-1. The first riser cage window 104 is configured to be interchangeably and removably connectable to the riser cage body 102 to assemble the riser cage bracket 150 such as a first riser cage bracket 150-1. For example, the first riser cage window 104 includes a third coupling portion 114 to enable the first riser cage window 104 to be removably connected to the riser cage body 102. In some examples, the length dimension “L_{W1}” of the first riser cage window 104 is disposed perpendicular to the length dimension “L_{B}” of the riser cage body 102 such that the third coupling portion 114 of the first riser cage window 104 is aligned with the first coupling portion 110 of the riser cage body 102. In such examples, the system 100 includes one or more fasteners (e.g., a first fastener 116 that interchangeably extends through the first coupling portion 110 of the riser cage body 102 and the third coupling portion 114 in the first riser cage window 104 to removably connect the first riser cage window 104 to the riser cage body 102 and assemble the first riser cage bracket 150-1. In some examples, the first riser cage bracket 150-1 is configured to support the expansion card 175 such as the first expansion card 175-1 having a full-height form factor. It may be noted herein, the “first expansion card” may also be referred to as a “full-height expansion card”. In such examples, the first riser cage window 104 further includes a fourth coupling portion 118 to enable the first riser cage window 104 to be coupled to the first expansion card 175-1, and thereby securing and supporting the first expansion card 175-1.

The second riser cage window 106 is another secondary structural support component of the riser cage bracket 150. The second riser cage window 106 has a length dimension “L_{W2}” extending along the second direction 20. The length dimension “L_{W2}” of the second riser cage window 106 may be associated with a low-profile configuration or a low-profile of the expansion card 175 such as the second expansion card 175-2. The second riser cage window 106 is configured to be interchangeably and removably connectable to the riser cage body 102 to assemble the riser cage bracket 150 such as a second riser cage bracket 150-2. For example, the second riser cage window 106 includes a fifth coupling portion 120 to enable the second riser cage window 106 to be removably connected to the riser cage body 102. In some examples, the length dimension “L_{W2}” of the second riser cage window 106 is disposed perpendicular to the length dimension “L_{B}” of the riser cage body 102 such that the fifth coupling portion 120 of the second riser cage window 106 is aligned with the first coupling portion 110 of the riser cage body 102. In such examples, the first fastener 116 is interchangeably extended through the first coupling portion 110 of the riser cage body 102 and the fifth coupling portion 120 of the second riser cage window 106 to removably connect the second riser cage window 106 to the riser cage body 102 and assemble the second riser cage bracket 150-2. In some examples, the second riser cage window 106 is configured to support the expansion card such as the second expansion card 175-2 having a low-profile form factor. It may be noted herein, the “second expansion card” may also be referred to as a “low-profile expansion card”. In some examples, the second riser cage window 106 further includes a sixth coupling portion 122 to enable the second riser cage window 106 to be coupled to the second expansion card 175-2, and thereby securing and supporting the second expansion card 175-2.

The riser card 108 may be an electronic card of an electronic device (not shown in FIGS. 1A-1C). The riser card 108 may be first coupled to the riser cage body 102 to get support from the riser cage body 102 and later detachably coupled to the electronic device to provision addition of one or more additional hardware components such as the expansion card 175 to the electronic device to satisfy/expand further requirements or functionality of the electronic device. The riser card 108 includes a seventh coupling portion 124 to enable the riser card 108 to be coupled to the riser cage body 102. In some examples, a length dimension (not labeled) of the riser card 108 is disposed parallel to the length dimension “L_{B}” of the riser cage body 102 such that the seventh coupling portion 124 of the riser card 108 is aligned with the second coupling portion 112 of the riser cage body 102. In such examples, the system 100 includes a second fastener 126 that extends through the seventh coupling portion 124 in the riser card 108 and second coupling portion 112 in the riser cage body 102 to couple the riser card 108 to the riser cage body 102. In some examples, the riser card 108 includes a circuit board 128, a first electrical connector 130, and a second electrical connector 174. The circuit board 128 is configured to be coupled to a primary system board (e.g., a motherboard, not shown) of the electronic device via the second electrical connector 174, which may detachably couple with a main connector of the primary system board or of a communications cable which is in turn coupled to the primary system board. The first electrical connector 130 is configured to be detachably coupled to a corresponding electrical connector 132 of the expansion card 175 such that the expansion card 175 is electrically connected to the primary system board via the riser card 108. In some examples, the riser card 108 is a peripheral component interconnect express (PCI-e) card.

The expansion card 175 may be another electronic card (e.g., a display card, graphics processing unit (GPU), accelerator module, networking interface module (NIC), etc.) that may be detachably coupled to the electronic device. The expansion card 175 includes another circuit board 134 and an electrical connector 132 (e.g., an electrical plug or socket) that can be engaged with (e.g., inserted into) the first electrical connector 130 of the riser card 108 to add and/or expand functionality of the electronic device. The expansion card 175 may be coupled to and supported by one of the riser cage windows 103. In some examples, the expansion card 175 may include a first expansion card 175-1 having a full-height form factor and a second expansion card 175-2 having a low-profile form factor. In some examples, the first expansion card 175-1 includes an eighth coupling portion 136 to enable the first expansion card 175-1 to be coupled to the first riser cage bracket 150-1. Similarly, the second expansion card 175-2 includes a ninth coupling portion 138 to enable the second expansion card 175-2 to be coupled to the second riser cage bracket 150-2. In some examples, each of the full-height expansion card and the low-profile expansion card is a PCI-e expansion card.

As discussed herein, in some examples, the first and second riser cage windows 104, 106 are configured to be interchangeably and removably connectable to the riser cage body 102 to assemble the riser cage bracket 150. In some examples, the first riser cage window 104 is selected from the system 100 to secure and provide support to the full-height expansion card 175-1. In such examples, the length dimension “L_{W1}” of the first riser cage window 104 is disposed perpendicular to the length dimension “L_{B}” of the riser cage body 102 such that the third coupling portion 114 of the first riser cage window 104 is aligned to the first coupling portion 110 of the riser cage body 102. Further, the first fastener 116 is interchangeably extended through the first and third coupling portions 110, 114 to removably connect the first riser cage window 104 to the riser cage body 102 and assemble the first riser cage bracket 150-1. As discussed herein, the riser card 108 is disposed in the riser cage body 102 of the first riser cage bracket 150-1 such that the seventh coupling portion 124 of the riser card 108 is aligned with the second coupling portion 112 of the riser cage body 102. Further, the second fastener 126 is extended through the seventh coupling portion 124 and second coupling portion 112 to couple the riser card 108 to the riser cage body 102 and form the riser cage assembly 2000 such as a first riser cage assembly 1500. In other words, the first riser cage bracket 150-1 and the riser card 108 together defines the first riser cage assembly 1500. In one or more examples, when the first riser cage window 104 is removably connected to the riser cage body 102, a first space 2140 is defined between the riser cage body 102 and the first riser cage window 104. In some examples, the first space 2140 has dimensions defined by the riser cage body 102 and the first riser cage window 104. These dimensions include a length or longitudinal dimension (also referred to herein as a first length “L₁”) extending along the first direction 10, a height or lateral dimension (also referred to herein as a first height “H₁”) in FIG. 1B and extending along the second direction 20, and a first width or radial dimension (not shown) extending along a third direction 30. These dimensions may collectedly be referred to herein as first dimensions. Further, the first dimensions of the first space 2140 may be compatible with a form factor (e.g., a full-height form factor) of the first expansion card 175-1 to allow the first expansion card 175-1 to be received by the first riser cage assembly 1500 in the first space 2140. In other words, the first expansion card 175-1 having the full-height form factor may have dimensions that are similar to (i.e., equal or slightly less than) the corresponding first dimensions of the first space 2140, thereby allowing the first riser cage bracket 150-1 of the first riser cage assembly 1500 to receive the first expansion card 175-1 in the first space 2140 (e.g., a length of the first expansion card 175-1 is equal to or less than “L₁”, a width of the first expansion card 175-1 is equal to or less than “H₁”, and so on). In some examples, when the first expansion card 175-1 is disposed in the first space 2140, the eighth coupling portion 136 in the first expansion card 175-1 is aligned with the fourth coupling portion 118 in the first riser cage window 104. In such examples, the system 100 further includes a third fastener 142 that engages with the fourth coupling portion 118 of the first riser cage window 104 and with the eighth coupling portion 136 of the first expansion card 175-1 to couple the first expansion card 175-1 to the first riser cage assembly 1500. In some examples, when the first expansion card 175-1 is disposed in the first space 2140 and coupled to the first riser cage bracket 150-1, the first electrical connector 130 of the riser card 108 is interchangeably detachably coupled to an electrical connector 132-1 of the first expansion card 175-1, thereby establishing an electrical connection between the primary system board of the electronic device and the first expansion card 175-1 through the riser card 108. Further, the system 100 may include a first fixture 144 and one or more second fixtures 146 to enable the first riser cage assembly 1500 to be installed to a chassis (not shown) of the electronic device. In particular, the first fixture 144 is disposed in the riser cage body 102 and the one or more second fixtures 146 is disposed in the first riser cage window 104, which extend into the chassis of the electronic device to install the first riser cage bracket 150-1 of the first riser cage assembly 1500 to the electronic device.

In some other examples, the second riser cage window 106 is selected from the system 100 to secure and provide support to the low-profile expansion card 175-2. In such examples, the length dimension “L_{W2}” of the second riser cage window 106 is disposed perpendicular to the length dimension “L_{B}” of the riser cage body 102 such that the fifth coupling portion 120 of the second riser cage window 106 is aligned to the first coupling portion 110 of the riser cage body 102. Further, the first fastener 116 is interchangeably extended through the first and fifth coupling portions 110, 120 to removably connect the second riser cage window 106 to the riser cage body 102 and assemble the second riser cage bracket 150-2. As discussed herein, the riser card 108 is disposed in the riser cage body 102 of the second riser cage bracket 150-2 such that the seventh coupling portion 124 of the riser card 108 is aligned with the second coupling portion 112 of the riser cage body 102. Further, the second fastener 126 is extended through the seventh coupling portion 124 and second coupling portion 112 to couple the riser card 108 to the riser cage body 102 and form a second riser cage assembly 1900. In other words, the second riser cage bracket 150-2 and the riser card 108 together defines the second riser cage assembly 1900. In one or more examples, when the second riser cage window 106 is removably connected to the riser cage body 102, a second space 3140 is defined between the riser cage body 102 and the second riser cage window 106. In some examples, the second space 3140 has dimensions defined by the riser cage body 102 and the second riser cage window 106. These dimensions include a length or longitudinal dimension (also referred to herein as a second length “L₂”) extending along the first direction 10, a height or lateral dimension (also referred to herein as a second height “H₂”) extending along the second direction 20, a second width or radial dimension (not shown) extending along the third direction 30. These dimensions may collectedly be referred to herein as second dimensions. Further, the second dimensions of the second space 3140 may be compatible to a form factor (e.g., a low-profile form factor) of the second expansion card 175-2 to allow the second expansion card 175-2 to be received by the second riser cage assembly 1900 in the second space 3140. In other words, the second expansion card 175-2 having the full-height form factor may have dimensions that are similar to (i.e., equal to slightly less than) the corresponding second dimensions of the second space 3140, thereby allowing the second riser cage bracket 150-2 of the second riser cage assembly 1900 to receive the second expansion card 175-2 in the second space 3140 (e.g., a length of the first expansion card 175-2 is equal to or less than “L₂”, a width of the first expansion card 175-2 is equal to or less than “H₂”, and so on). In some examples, when the second expansion card 175-2 is disposed in the second space 3140, the ninth coupling portion 138 in the second expansion card 175-2 is aligned with the sixth coupling portion 122 in the second riser cage window 106. In such examples, the system 100 further includes a fourth fastener 152 that engages with the sixth coupling portion 122 of the second riser cage window 106 and with the ninth coupling portion 138 of the second expansion card 175-2 to couple the second expansion card 175-2 to the second riser cage assembly 1900. In some examples, when the second expansion card 175-2 is disposed in the second space 3140 and coupled to the second riser cage bracket 150-2, the first electrical connector 130 of the riser card 108 is interchangeably detachably coupled to an electrical connector 132-2 of the second expansion card 175-2, thereby establishing an electrical connection between the primary system board of the electronic device and the second expansion card 175-2 through the riser card 108. Further, the system 100 includes the first fixture 144 and one or more third fixtures 154 to enable the second riser cage bracket 150-2 to be installed to the chassis of the electronic device. In particular, the first fixture 144 is disposed in the riser cage body 102 and the one or more third fixtures 154 is disposed in the second riser cage window 106, which extend into the chassis of the electronic device to install the second riser cage assembly 1900 to the electronic device.

In some examples, each of the first riser cage window 104 and the second riser cage window 106 have different lengths (e.g., the length dimension “L_{W1}” of the first riser cage window 104 and the length dimension “L_{W2}” of the second riser cage window 106) along their respective longitudinal dimensions. For example, in FIGS. 1A-1C, the longitudinal dimension of each of the first and second riser cage windows 104, 106, respectively, extends along the second direction 20. Specifically, respective length dimensions of the first and second spaces 2140, 3140 may be defined by the length of the riser cage body 102, respective width dimensions of the first and second spaces 2140, 3140 may be defined by a width of the riser cage body 102 and/or a width of the first and second riser cage windows 104, 106, and respective height dimensions of the first and second spaces 2104, 3140 may be defined respective lengths of the first and second riser cage windows 104, 106. Thus, each of the first space 2140 and the second space 3140 have equal lengths, equal widths, and different heights. For example, the first length “L₁” and the second length “L₂” are equal, the first width and the second width may be equal, and the first height “H₁” and the second height “H₂” are different. In particular, the first height “H₁” is greater than the second height “H₂”.

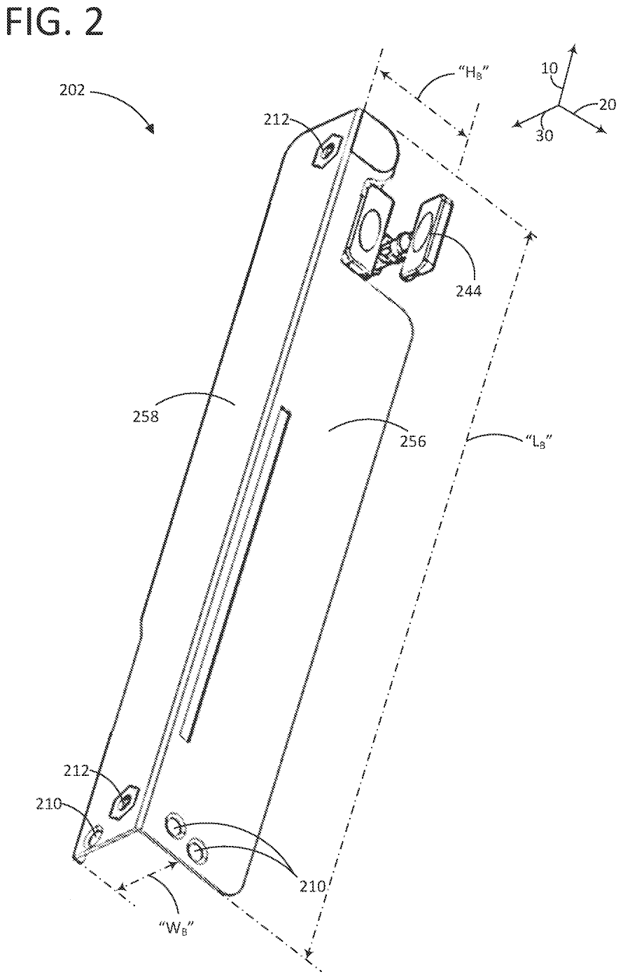

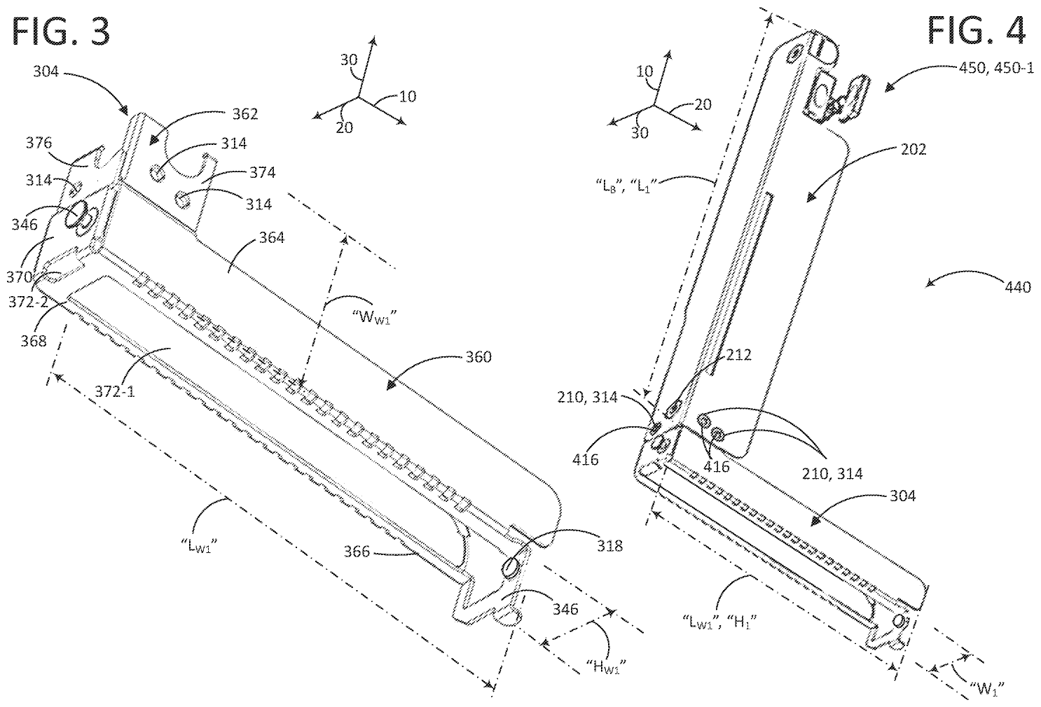

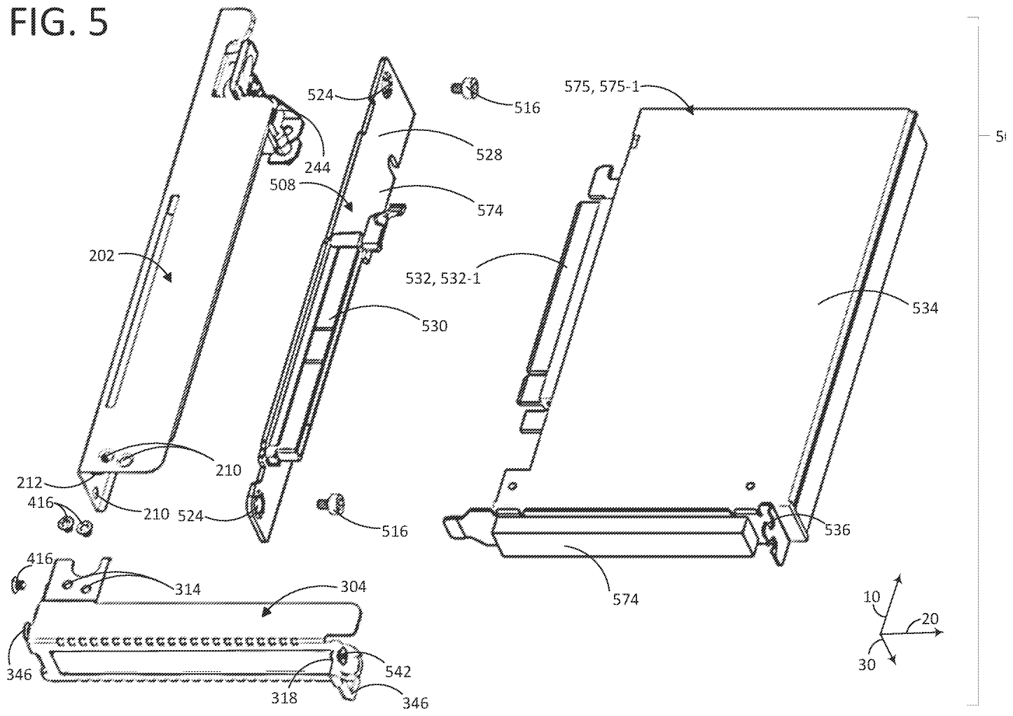

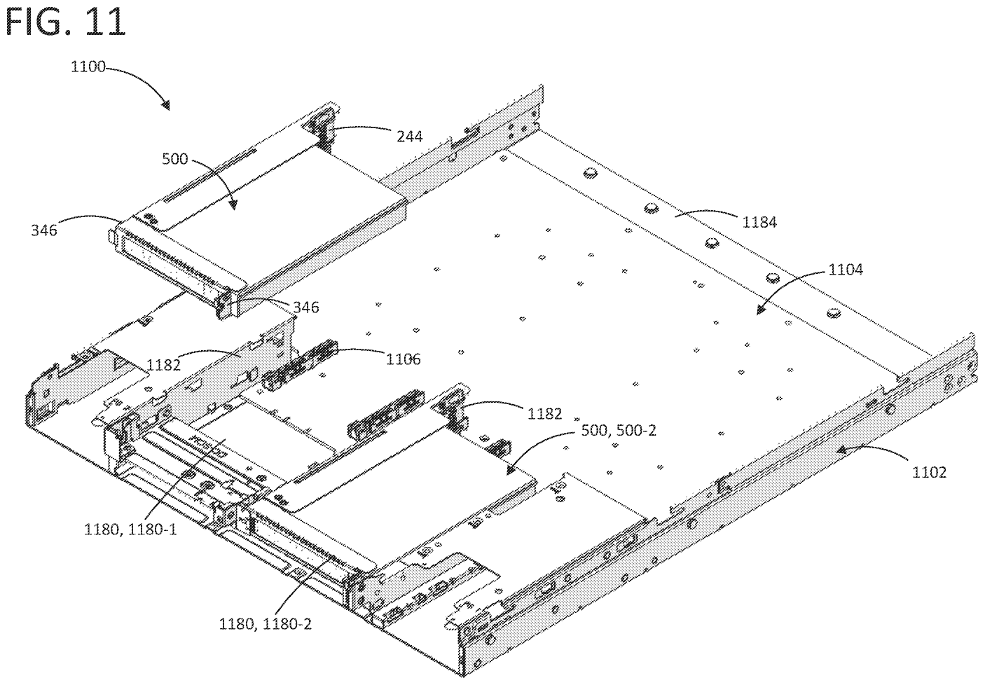

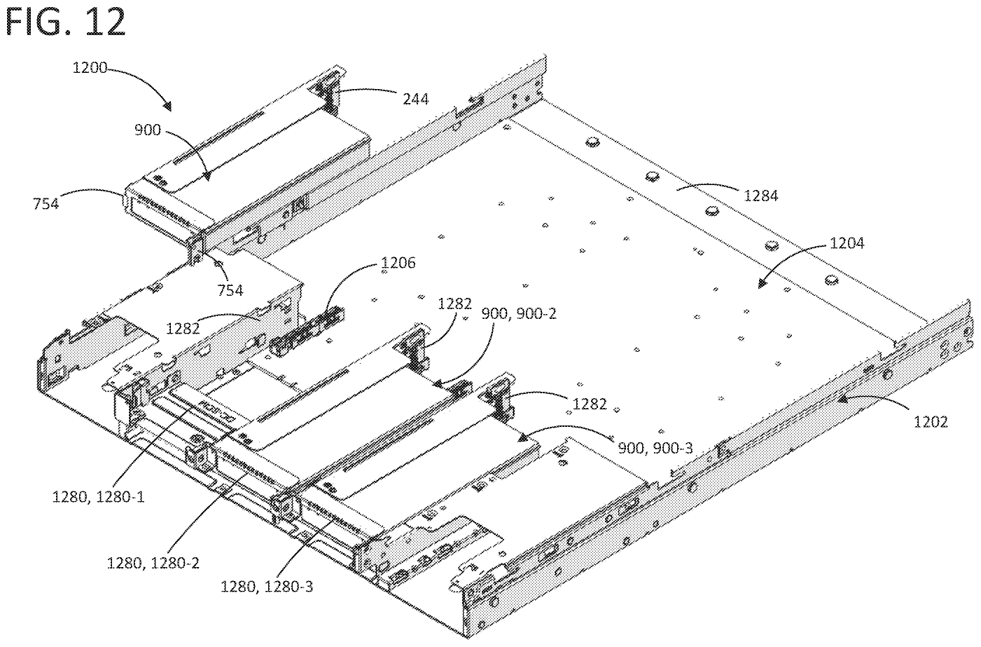

FIG. 2 depicts a perspective view of a riser cage body 202. In some examples, the riser cage body 202 is a main structural support component of a riser cage bracket 450 (see, FIG. 4). The riser cage body 202 includes a first arm 256 and a second arm 258 disposed perpendicularly to the first arm 256 and coupled to the first arm 256 to define an “L” shaped structure. In some examples, the riser cage body 202 includes a length dimension “L_{B}” extending along a first direction 10, a height dimension “H_{B}” extending along a second direction 20, and a width dimension “W_{B}” extending along a third direction 30. One end (not labeled) of the first arm 256 includes a first fixture 244 which may enable the riser cage body 202 to be installed to a chassis 1102 (see, FIG. 11) of an electronic device 1100 (see, FIG. 11) or to a chassis 1202 (see, FIG. 12) of an electronic device 1200 (see, FIG. 12). Further, other end of the first arm 256 includes first coupling portions 210, e.g., apertures. Similarly, the other corresponding end of the second arm 258 also includes the first coupling portions 210, e.g., apertures. In one or more examples, the first coupling portions 210 may enable the riser cage body 202 to be interchangeably and removably connect to a first riser cage window 304 (see, FIG. 3) or a second riser cage window 804 (see, FIG. 8). Further, the end portions of the second arm 258 further includes a second coupling portions 212 e.g., apertures. In one or more examples, the second coupling portions 212 may enable the riser cage body 102 to be coupled to a riser card 508 (see, FIG. 5).

FIG. 3 depicts a perspective view of a first riser cage window 304. In some examples, the first riser cage window 304 is a secondary structural support component of the riser cage bracket 450 (see, FIG. 4). The first riser cage window 304 includes a first attachment component 360 and a second attachment component 362. The second attachment component 362 is disposed parallel to the first attachment component 360 and coupled to one end of the first attachment component 360.

In some examples, the first attachment component 360 has a first support wall 364, a second support wall 366, a third support wall 368, and a fourth support wall 370. The first and second support walls 364, 366 are disposed parallel to each other, and the third and fourth support walls 368, 370 are disposed perpendicular to each other and lateral sides of the third side wall 367 and the fourth support wall 370 are coupled to each other. Further, one longitudinal side and one radial side of the first support wall 364 are coupled to a corresponding longitudinal side of the third support wall 365 and a corresponding radial side of the fourth support wall 370, respectively. Similarly, one longitudinal side and one radial side of the second support wall 366 are coupled to another corresponding longitudinal side of the third support wall 368 and another corresponding radial side of the fourth support wall 370, respectively. Accordingly, the first, second, third, and fourth support walls 364, 366, 368, 370 are coupled such the first attachment component 360 defines a hollow section therebetween. The second attachment component 362 includes a first wall 374 and a second wall 376 disposed perpendicularly to the first wall 374 and coupled to the first wall 374 to define an “L” shaped structure. In some examples, the first wall 374 is further coupled to one end portion of another longitudinal side of the first support wall 364. Similarly, the second wall 376 is further coupled to another lateral side of the fourth support wall 370. In one or more examples, the first attachment component 360 may be configured to receive a portion of a first expansion card 575-1 (see, FIG. 5), and the second attachment component 362 may be configured to be mounted within a portion of the riser cage body 202 having the first coupling portion 210. In such examples, the third support wall 368 includes a first opening 372-1 that allows the portion of the first expansion card 575-1 to extend beyond the first attachment component 360. Similarly, the fourth support wall 370 includes a second opening 372-2 that allows another portion of the first expansion card 575-1 to extend beyond the first attachment component 360. The second attachment component 362 may be mounted within a portion of the riser cage body 202 having the first coupling portion 210 to enable the first riser cage window 304 to be coupled to the riser cage body 202. For example, the first wall 374 and the second wall 376 of the second attachment component 362 include third coupling portions 314, e.g., aperture to enable the first riser cage window 304 to be removably connected to the riser cage body 202. It may be noted that the longitudinal side may extend along a first direction 10, the lateral side may extend along the second direction 20, and the radial side may extend along the third direction 30.

In some examples, a free end of the third support wall 368 of the first attachment component 360 includes one of the second fixture 346 and the fourth support wall 368 includes other one of the second fixture 346. The third support wall 368 further includes a fourth coupling portion 318, e.g., aperture to enable the first riser cage window 304 to be coupled to the first expansion card 575-1, and thereby secure and support the first expansion card 575-1. In one or more examples, the second fixtures 346 may enable the first riser cage window 304 to be installed to the chassis 1102. In one or more examples, the first riser cage window 304 has a length dimension “L_{W1}” extending along the first direction 10. In particular, the length dimension “L_{W1}” may be defined by the first attachment component 360. The first riser cage window 304 further has a height dimension “H_{W1}” extending along the second direction 20. In particular, the height dimension “H_{W1}” may be defined by each of the first attachment component 360 and the second attachment component 362. Further, the first riser cage window 304 has a width dimension “W_{W1}” extending along the third direction 30. In particular, the width dimension “W_{W1}” may be defined by the first attachment component 360 and the second attachment component 362 together. In some examples, the length dimension “L_{W1}” of the first riser cage window 304 may be associated with a full-height configuration or a full-height of the first expansion card 575-1.

FIG. 4 depicts a perspective view of a riser cage bracket 450 such as a first riser cage bracket 450-1. In one or more examples, the first riser cage bracket 450-1 includes a riser cage body 202 and a first riser cage window 304. The first riser cage window 304 is configured to be interchangeably and removably connectable to the riser cage body 202 to assemble the riser cage bracket 450-1. In some examples, the length dimension “L_{W1}” of the first riser cage window 304 is disposed perpendicular to the length dimension “L_{B}” of the riser cage body 202 such that the third coupling portion 314 of the first riser cage window 304 is aligned with the first coupling portion 210 of the riser cage body 202. In particular, the third coupling portions 314 in the first wall 374 are aligned with the first coupling portions 210 in the first arm 256. Similarly, the third coupling portion 314 in the second wall 376 is aligned with the first coupling portion 210 in the second arm 258. In such examples, each of the one or more first fasteners 416 is interchangeably extended through a corresponding first coupling portion 210 of the riser cage body 202 and a corresponding third coupling portion 314 in the first riser cage window 304 to removably connect the first riser cage window 304 to the riser cage body 202 and assemble the first riser cage bracket 450-1.

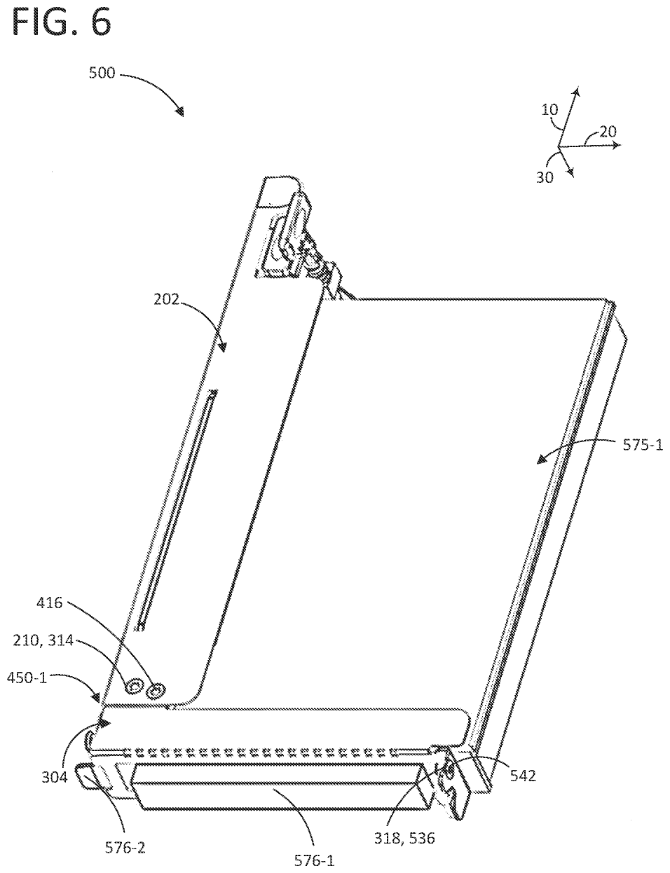

In one or more examples, when the first riser cage window 304 is removably connected to the riser cage body 202, a first space 440 is defined between the riser cage body 202 and the first riser cage window 304. In some examples, the first space 440 has dimensions defined by the riser cage body 202 and the first riser cage window 304. These dimensions include a length or longitudinal dimension (also referred to herein as a first length “L₁”) extending along the first direction 10, a height or lateral dimension (also referred to herein as a first height “H₁”) extending along the second direction 20, a width or radial dimension (also referred to herein as a first width “W₁”) extending along a third direction 30. These dimensions may collectedly be referred to herein as first dimensions. Further, the first dimensions of the first space 440 may be compatible with a form factor (e.g., a full-height form factor) of the first expansion card 575-1 to allow the first expansion card 575-1 to be received by a first riser cage assembly 500 (see, FIGS. 5-6) in the first space 440. In other words, the first expansion card 575-1 having the full-height form factor may have dimensions that are similar to (i.e., equal or slightly less than) the corresponding first dimensions of the first space 440, thereby allowing the first riser cage bracket 450-1 of the first riser cage assembly 500 to receive the first expansion card 575-1 in the first space 440 (e.g., a length of the first expansion card 575-1 is equal to or less than “L₁”, a width of the first expansion card 575-1 is equal to or less than “H₁”, and so on).

FIG. 5 depicts an exploded perspective view of a first riser cage assembly 500 having a riser cage bracket 450, a riser card 508, and a first expansion card 575-1. FIG. 6 depicts an assembled perspective view of the first riser cage assembly 500 of FIG. 5. In the description hereinafter, FIGS. 5-6 are described concurrently for ease of illustration.

As discussed hereinabove, the riser cage bracket 450 such as the first cage bracket 450-1 includes a riser cage body 202 and a first riser cage window 304. In some examples, the riser cage body 202 has first coupling portions 210, a second coupling portion 212, and a first fixture 244. Similarly, the first riser cage window 304 has third coupling portions 314, a fourth coupling portion 318, and second fixtures 346. The first riser cage bracket 450-1 further includes one or more first fasteners 416.

The riser card 508 may be an electronic card of an electronic device 1100 (see, FIG. 11). The riser card 508 includes a seventh coupling portion 524 e.g., aperture to enable the riser card 508 to be coupled to the riser cage body 502. In some examples, a length dimension (not labeled) of the riser card 508 is disposed parallel to the length dimension “L_{B}” of the riser cage body 202 such that the seventh coupling portion 524 of the riser card 508 is aligned with the second coupling portion 212 of the riser cage body 202. In some examples, the riser card 508 includes a circuit board 528, a first electrical connector 530, and a second electrical connector 574 (e.g., golden fingers). In one or more examples, the first electrical connector 530 and the second electrical connector 574 are disposed perpendicular to each other and coupled to the circuit board 528. In some examples, the second electrical connector 574 is configured to be coupled to a primary system board 1104 (e.g., motherboard, see, FIG. 11) of the electronic device 1100. In particular, the first electrical connector 530 is configured to be aligned with an electrical connector 532 of the expansion card 575 and may be detachably coupled to the electrical connector 532 such that the expansion card 575 is electrically connected to the primary system board 1104 via the riser card 508. In some examples, the riser card 508 is a peripheral component interconnect express (PCI-e) card. The first riser cage bracket 450-1 further includes one or more second fasteners 516.

The expansion card 575 may be another electronic card (e.g., a display card, graphics processing unit (GPU), accelerator module, networking interface module (NIC), etc.) that may be detachably coupled to the electronic device 1100. In some examples, the expansion card 575 may be a first expansion card 575-1 having a full-height form factor. In some examples, the first expansion card 575-1 includes an eighth coupling portion 536 e.g., aperture to enable the first expansion card 575-1 to be coupled to the first riser cage bracket 450-1. The first expansion card 575-1 includes another circuit board 534 and an electrical connector 532 (e.g., an electrical plug or socket) that can be engaged with (e.g., inserted into) the first electrical connector 530 of the riser card 508 to add and/or expand functionality of the electronic device 1100. In some examples, the full-height expansion card 575-1 is a PCI-e expansion card. The first riser cage bracket 450-1 further includes one or more third fasteners 542.

In some examples, the first riser cage window 304 is selected to secure and provide support to the full-height expansion card 575-1. In such examples, the length dimension “L_{W1}” (see, FIG. 3) of the first riser cage window 304 is disposed perpendicular to the length dimension “L_{B}” (see, FIG. 2) of the riser cage body 202 such that the third coupling portion 314 of the first riser cage window 304 is aligned to the first coupling portion 210 of the riser cage body 202. Further, the first fastener 416 is interchangeably extended through the first and third coupling portions 210, 314 to removably connect the first riser cage window 304 to the riser cage body 202 and assemble the first riser cage bracket 450-1. The riser card 508 is disposed in the riser cage body 202 of the riser cage bracket 450-1 such that the seventh coupling portion 524 of the riser card 508 is aligned with the second coupling portion 212 of the riser cage body 202. Further, the second fastener 526 is extended through the seventh coupling portion 524 and second coupling portion 212 to couple the riser card 508 to the riser cage body 202 and form the first riser cage assembly 500. In other words, the first riser cage bracket 450-1 and the riser card 508 together defines the first riser cage assembly 500. In such examples, the riser card 508 coupled to the riser cage body 202 gets support from the first riser cage bracket 450-1. In one or more examples, when the first riser cage window 304 is removably connected to the riser cage body 202, a first space 440 (see, FIG. 4) is defined between the riser cage body 202 and the first riser cage window 304. In some examples, the first space 440 has a first dimension defined by the riser cage body 202 and the first riser cage window 304. In particular, the first dimension of the first space 440 may be compatible with a form factor (e.g., a full-height form factor) of the first expansion card 575-1 to allow the first expansion card 575-1 to be received by the first riser cage assembly 500. In other words, the first expansion card 575-1 having the full-height form factor may have a dimension that is equal to the first dimension of the first space 440, thereby allowing the first riser cage assembly 500 to receive the first expansion card 575-1 in the first space 440. In some examples, when the first expansion card 575-1 is disposed in the first space 440, a portion 576-1 of the first expansion card 575-1 protrudes through the first opening 372-1 in the first riser cage window 304 and extends beyond the first riser cage bracket 450-1. Similarly, another portion 576-2 of the first expansion card 575-1 protrudes through the second opening 372-2 in the first riser cage window 304 and extends beyond the first riser cage bracket 450-1. Further, when the first expansion card 575-1 is disposed in the first space 540, the eighth coupling portion 536 in the first expansion card 575-1 is aligned with the fourth coupling portion 318 in the first riser cage window 304. In such examples, the third fastener 542 is engaged with the fourth coupling portion 318 of the first riser cage window 304 and with the eighth coupling portion 536 of the first expansion card 575-1 to couple the first expansion card 575-1 to the first riser cage assembly 500. In some examples, when the first expansion card 575-1 is disposed in the first space 440 and coupled to the first riser cage bracket 450-1, the first electrical connector 530 of the riser card 508 is interchangeably detachably coupled to an electrical connector 532-1 of the first expansion card 575-1 and the second electrical connector 574 of the riser card 508 is detachably coupled to a main electrical connector 1106 (see, FIG. 11) of the primary system board 1104 of the electronic device 1100, thereby establishing an electrical connection between the primary system board 1104 and the first expansion card 575-1 through the riser card 508.

Since the first riser cage bracket 450-1 may be easily assembled by interchangeably and removably connecting the first riser cage window 304 onto a common riser cage body 202 to form the new riser cage bracket 450-1 that is compatible with the first expansion card 575-1, the new riser cage bracket 450-1 provides flexibility, serviceability, and benefit from supply chain in terms of reducing number of ready-made riser cage brackets needed in the inventory. Further, the first riser cage bracket 450-1 is inexpensive to assemble, maintain, and replace, since the riser cage body 202 and the riser card 508 are retained, and only a pre-installed riser cage window that is incompatible with the first expansion card 575-1 is replaced with the first riser cage window 304 that is compatible with the first expansion card 575-1 to assemble the first riser cage bracket 450-1 of the first riser cage assembly 500.

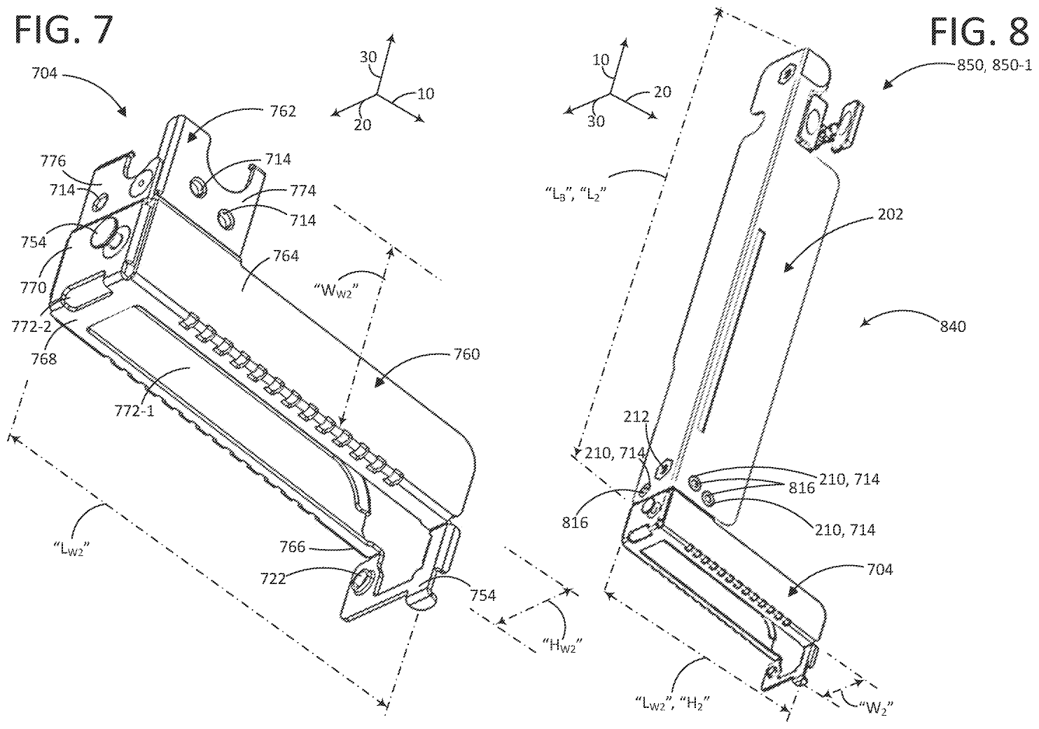

FIG. 7 depicts a perspective view of a second riser cage window 704. In some examples, the second riser cage window 704 is a secondary structural support component of the riser cage bracket 850 (see, FIG. 8). The second riser cage window 704 includes a first attachment component 760 and a second attachment component 762. The second attachment component 762 is disposed parallel to the first attachment component 760 and coupled to one end of the first attachment component 760.

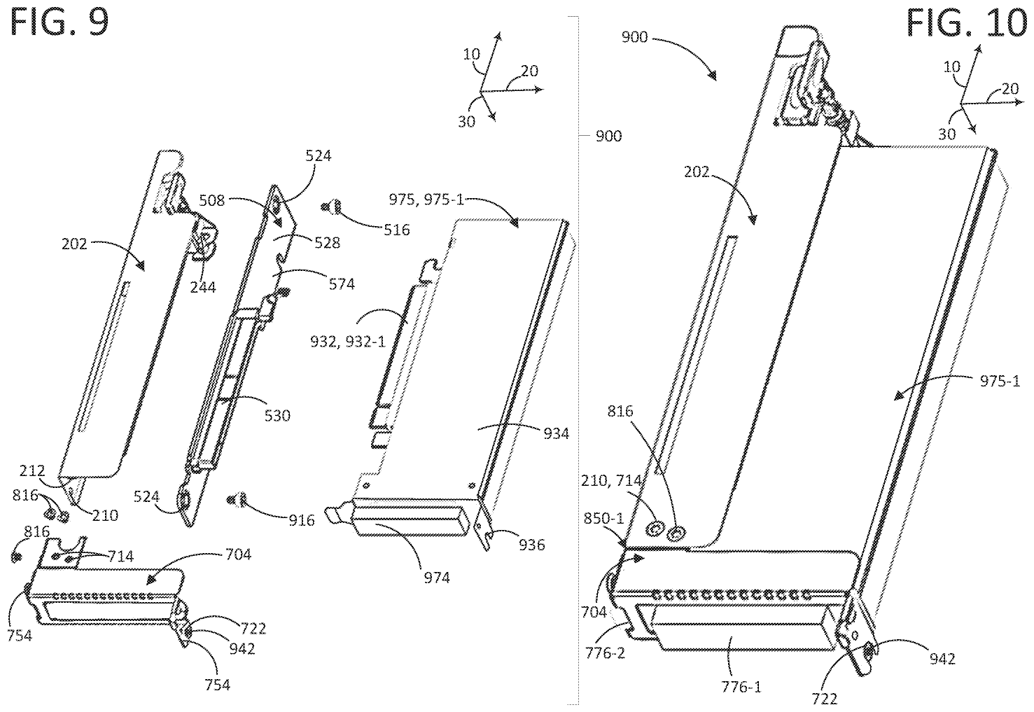

In some examples, the first attachment component 760 has a first support wall 764, a second support wall 766, a third support wall 768, and a fourth support wall 770. The first and second support walls 764, 766 are disposed parallel to each other, and the third and fourth support walls 768, 770 are disposed perpendicular to each other and lateral sides of the third side wall 767 and the fourth support wall 770 are coupled to each other. Further, one longitudinal side and one radial side of the first support wall 764 are coupled to a corresponding longitudinal side of the third support wall 768 and a corresponding radial side of the fourth support wall 770, respectively. Similarly, one longitudinal side and one radial side of the second support wall 766 are coupled to another corresponding longitudinal side of the third support wall 768 and another corresponding radial side of the fourth support wall 770, respectively. Accordingly, the first, second, third, and fourth support walls 764, 766, 768, 770 are coupled such the first attachment component 760 defines a hollow section therebetween. The second attachment component 762 includes a first wall 774 and a second wall 776 disposed perpendicularly to the first wall 774 and coupled to the first wall 774 to define an “L” shaped structure. In some examples, the first wall 774 is further coupled to one end portion of another longitudinal side of the first support wall 764. Similarly, the second wall 776 is further coupled to another lateral side of the fourth support wall 770. In one or more examples, the first attachment component 760 may be configured to receive a portion of an expansion card 975 such as a second expansion card 975-1 (see, FIG. 9), and the second attachment component 762 may be configured to be mounted within a portion of the riser cage body 202 (see, FIG. 2) having the first coupling portion 210. In such examples, the third support wall 768 includes a first opening 772-1 that allows the portion of the second expansion card 975-1 to extend beyond the first attachment component 760. Similarly, the fourth support wall 770 includes a second opening 772-2 that allows another portion of the second expansion card 975-1 to extend beyond the first attachment component 760. The second attachment component 762 may be mounted within a portion of the riser cage body 202 having the first coupling portion 210 to enable the second riser cage window 704 to be coupled to the riser cage body 202. For example, the first wall 774 and the second wall 776 of the second attachment component 762 include third coupling portions 714, e.g., apertures to enable the second riser cage window 704 to be removably connected to the riser cage body 202. It may be noted that the longitudinal side may extend along a first direction 10, the lateral side may extend along the second direction 20, and the radial side may extend along the third direction 30.

In some examples, a free end of the third support wall 768 of the first attachment component 760 includes one of the third fixture 754 and the fourth support wall 770 includes other one of the third fixture 754. The third support wall 768 further includes a sixth coupling portion 722, e.g., aperture to enable the second riser cage window 704 to be coupled to the second expansion card 975-1, and thereby secure and support the second expansion card 975-1. In one or more examples, the third fixtures 754 may enable the second riser cage window 704 to be installed to the chassis 1202. In one or more examples, the second riser cage window 704 has a length dimension “L_{W2}” extending along the first direction 10. In particular, the length dimension “L_{W2}” may be defined by the first attachment component 760. The second riser cage window 704 further has a height dimension “H_{W2}” extending along the second direction 20. In particular, the height dimension “H_{W2}” may be defined by each of the first attachment component 760 and the second attachment component 762. Further, the second riser cage window 704 has a width dimension “W_{W2}” extending along the third direction 30. In particular, the width dimension “W_{W2}” may be defined by the first attachment component 760 and the second attachment component 762 together. In some examples, the length dimension “L_{W2}” of the second riser cage window 704 may be associated with a low-profile configuration or a low-profile of the second expansion card 975-1.

FIG. 8 depicts a perspective view of a riser cage bracket 850 such as a second riser cage bracket 850-1. In one or more examples, the second riser cage bracket 850-1 includes a riser cage body 202 and a second riser cage window 704. The second riser cage window 704 is configured to be interchangeably and removably connectable to the riser cage body 202 to assemble the riser cage bracket 850-1. In some examples, the length dimension “L_{W2}” of the second riser cage window 704 is disposed perpendicular to the length dimension “L_{B}” of the riser cage body 202 such that the third coupling portion 714 of the second riser cage window 704 is aligned with the first coupling portion 210 of the riser cage body 202. In particular, the third coupling portions 714 in the first wall 774 are aligned with the first coupling portions 210 in the first arm 256. Similarly, the third coupling portion 714 in the second wall 776 is aligned with the first coupling portion 210 in the second arm 258. In such examples, each of the one or more first fasteners 816 is interchangeably extended through a corresponding first coupling portion 210 of the riser cage body 202 and a corresponding third coupling portion 714 in the second riser cage window 704 to removably connect the second riser cage window 704 to the riser cage body 202 and assemble the second riser cage bracket 850-1.

In one or more examples, when the second riser cage window 704 is removably connected to the riser cage body 202, a second space 840 is defined between the riser cage body 202 and the second riser cage window 704. In some examples, the first space 840 has dimensions defined by the riser cage body 202 and the second riser cage window 704. These dimensions include a length or longitudinal dimension (also referred to herein as a second length “L₂”) extending along the first direction 10, a height or lateral dimension (also referred to herein as a second height “H₂”) extending along the second direction 20, and a width or radial dimension (also referred to herein as a second width “W₂”) extending along a third direction 30. These dimensions may collectedly be referred to herein as second dimensions. Further, the second dimensions of the second space 840 may be compatible with a form factor (e.g., a low-profile form factor) of the second expansion card 975-1 to allow the second expansion card 975-1 to be received by a second riser cage assembly 900 (see, FIGS. 9-10) in the second space 840. In other words, the second expansion card 975-1 having the low-profile form factor may have dimensions that are similar to (i.e., equal or slightly less than) the second dimensions of the second space 840, thereby allowing the second riser cage bracket 850-1 of the second riser cage assembly 900 to receive the second expansion card 975-1 in the second space 840 (e.g., a length of the second expansion card 975-1 is equal to or less than “L₂”, a width of the second expansion card 975-1 is equal to or less than “H₂”, and so on).

FIG. 9 depicts an exploded perspective view of a second riser cage assembly 900 having a riser cage bracket 850, a riser card 508, and a second expansion card 975-1. FIG. 10 depicts an assembled perspective view of the second riser cage assembly 900 of FIG. 9. In the description hereinafter, FIGS. 5-6 are described concurrently for ease of illustration.

As discussed hereinabove, the riser cage bracket 850, such as the second cage bracket 850-1 includes a riser cage body 202 and a second riser cage window 704. In some examples, the riser cage body 202 has first coupling portions 210, a second coupling portion 212, and a first fixture 244. Similarly, the second riser cage window 704 has third coupling portions 714, a sixth coupling portion 722, and third fixtures 754. The second riser cage bracket 850-1 further includes one or more first fasteners 816.

The riser card 508 may be an electronic card of an electronic device 1200 (see, FIG. 12). The riser card 508 depicted in the example of FIGS. 9-10 are same as the riser card 508 depicted in the example of FIGS. 5-6. The riser card 508 includes a seventh coupling portion 524 e.g., aperture to enable the riser card 508 to be coupled to the riser cage body 502. In some examples, a length dimension (not labeled) of the riser card 508 is disposed parallel to the length dimension “L_{B}” of the riser cage body 202 such that the seventh coupling portion 524 of the riser card 508 is aligned with the second coupling portion 212 of the riser cage body 202. In some examples, the riser card 508 includes a circuit board 528, a first electrical connector 530, and a second electrical connector 574 (e.g., golden fingers). In one or more examples, the first electrical connector 530 and the second electrical connector 574 are disposed perpendicular to each other and coupled to the circuit board 528. In some examples, the second electrical connector 574 is configured to be coupled to a primary system board 1204 (e.g., motherboard, see, FIG. 12) of the electronic device 1200. In particular, the first electrical connector 530 is configured to be aligned with an electrical connector 932 of the expansion card 975 and may be detachably coupled to the electrical connector 932 such that the expansion card 975 is electrically connected to the primary system board 1204 via the riser card 508. In some examples, the riser card 508 is a peripheral component interconnect express (PCI-e) card. The first riser cage bracket 850-1 further includes one or more second fasteners 916.

The expansion card 975 may be another electronic card (e.g., a display card, graphics processing unit (GPU), accelerator module, networking interface module (NIC), etc.) that may be detachably coupled to the electronic device 1200. In some examples, the expansion card 975 may be a second expansion card 975-1 having a low-profile form factor. In some examples, the second expansion card 975-1 includes a ninth coupling portion 938 e.g., aperture to enable the second expansion card 975-1 to be coupled to the second riser cage bracket 850-1. The second expansion card 975-1 includes another circuit board 934 and an electrical connector 932-1 (e.g., an electrical plug or socket) that can be engaged with (e.g., inserted into) the first electrical connector 530 of the riser card 508 to add and/or expand functionality of the electronic device 1200. In some examples, the low-profile expansion card 975-1 is a PCI-e expansion card. The second riser cage bracket 850-1 further includes one or more third fasteners 942.

In some examples, the second riser cage window 704 is selected to secure and provide support to the low-profile expansion card 975-1. In such examples, the length dimension “L_{W2}” (see, FIG. 7) of the second riser cage window 704 is disposed perpendicular to the length dimension “L_{B}” (see, FIG. 2) of the riser cage body 202 such that the third coupling portion 714 of the second riser cage window 704 is aligned to the first coupling portion 210 of the riser cage body 202. Further, the first fastener 816 is interchangeably extended through the first and third coupling portions 210, 714 to removably connect the second riser cage window 704 to the riser cage body 202 and assemble the second riser cage bracket 850-1. The riser card 508 is disposed in the riser cage body 202 of the riser cage bracket 850-1 such that the seventh coupling portion 524 of the riser card 508 is aligned with the second coupling portion 212 of the riser cage body 202. Further, the second fastener 526 is extended through the seventh coupling portion 524 and second coupling portion 212 to couple the riser card 508 to the riser cage body 202 and form the second riser cage assembly 900. In other words, the second riser cage bracket 850-1 and the riser card 508 together defines the second riser cage assembly 900. In such examples, the riser card 508 coupled to the riser cage body 202 gets support from the second riser cage bracket 850-1. In one or more examples, when the second riser cage window 704 is removably connected to the riser cage body 202, a second space 840 (see, FIG. 8) is defined between the riser cage body 202 and the second riser cage window 804. In some examples, the second space 840 has a second dimension defined by the riser cage body 202 and the second riser cage window 704. In particular, the second dimension of the second space 840 may be compatible with a form factor (e.g., a low-profile form factor) of the second expansion card 975-1 to allow the second expansion card 975-1 to be received by the second riser cage assembly 900. In other words, the second expansion card 975-1 having the low-profile form factor may have a dimension that is equal to the second dimension of the second space 840, thereby allowing the second riser cage assembly 900 to receive the second expansion card 975-1 in the second space 840. In some examples, when the second expansion card 975-1 is disposed in the second space 840, a portion 976-1 of the second expansion card 975-1 protrudes through the second opening 772-1 in the second riser cage window 704 and extends beyond the second riser cage bracket 850-1. Similarly, another portion 776-2 of the second expansion card 975-1 protrudes through the second opening 772-2 in the second riser cage window 704 and extends beyond the second riser cage bracket 850-1. Further, when the second expansion card 975-1 is disposed in the second space 840, the ninth coupling portion 938 in the second expansion card 975-1 is aligned with the sixth coupling portion 722 in the second riser cage window 704. In such examples, the third fastener 942 is engaged with the sixth coupling portion 722 of the second riser cage window 704 and with the ninth coupling portion 938 of the second expansion card 975-1 to couple the second expansion card 975-1 to the second riser cage assembly 900. In some examples, when the second expansion card 975-1 is disposed in the second space 840 and coupled to the second riser cage bracket 850-1, the first electrical connector 530 of the riser card 508 is interchangeably detachably coupled to an electrical connector 932-1 of the second expansion card 975-1 and the second electrical connector 574 of the riser card 508 is detachably coupled to a main electrical connector 1206 (see, FIG. 12) of the primary system board 1204 of the electronic device 1200, thereby establishing an electrical connection between the primary system board 1204 and the second expansion card 975-1 through the riser card 508.

Since the second riser cage bracket 850-1 may be easily assembled by interchangeably and removably connecting the second riser cage window 704 onto a common riser cage body 202 to form the new riser cage bracket 850-1 that is compatible with the second expansion card 975-1, the new riser cage bracket 850-1 provides flexibility, serviceability, and benefit from supply chain in terms of reducing number of ready-made riser cage brackets needed in the inventory. Further, the second riser cage bracket 850-1 is inexpensive to assemble, maintain, and replace, since the riser cage body 202 and the riser card 508 are retained, and only a pre-installed riser cage window that is incompatible with the second expansion card 975-1 is replaced with the second riser cage window 704 that is compatible with the second expansion card 975-1 to assemble the second riser cage bracket 850-1 of the second riser cage assembly 900.

FIG. 11 depicts an exploded perspective view of an electronic device 1100 having a first riser cage assembly 500 of FIG. 6. In some examples, the electronic device 1100 may be a computer (e.g., server, storage device, etc.), networking device (e.g., transceiver, wireless access point, router, switch, etc.), or the like. In the example of FIG. 11, the electronic device 1100 is a server. In some examples, the electronic device 1100 includes a chassis 1102 and electronic components such as a primary system board 1104 (e.g., a motherboard), and the first riser cage assembly 500.

The chassis 1102 includes a plurality of passageways 1180 defined by brackets 1182 coupled to a base 1184 of the chassis 1102. For example, the chassis 1102 includes two passageways 1180, a first passageway 1180-1 and a second passageway 1180-2, where each passageway is configured to receive the first riser cage assembly 500 and another first riser cage assembly 500-2. The primary system board 1104 may be a printed circuit board of the electronic device 1100 having electrical circuitry integrated therein, such as conductive strips disposed on or in dielectric sheets, and to which one or more integrated circuits (IC), one or more input/outputs ports, power ports, electronic components, or the like are attached. In some examples, the primary system board 1104 includes a main electrical connector 1106.

In some examples, the first riser cage assembly 500 is disposed in the first passageway 1180-1 of the chassis 1102. In such examples, when the first riser cage assembly 500 is disposed in the first passageway 1108-1, the second electrical connector 574 (see, FIG. 5) of the riser card 508 is interchangeably detachably coupled to the main electrical connector 1106 of the primary system board 1104 to establish an electrical connection between the primary system board 1104 and the first expansion card 575-1 through the riser card 508, thereby allowing addition of the first expansion card 575-1 to the electronic device 1100 to satisfy/expand further requirements or functionality of the electronic device 1100. Further, in some examples, the first fixture 244 and the one or more second fixtures 346 of the first riser cage assembly 500 is coupled to the chassis 1120 (e.g., brackets 1182 and base 1184 of the chassis 1102, for example) so as to enable the first riser cage assembly 500 to be installed to the electronic device 1100. In the example of FIG. 11, the other first riser cage assembly 500-2 is shown to be pre-disposed in a second slot 1180-2 such that a riser card (not shown) of the other first riser cage assembly 500-2 is connected to a second main connector (not shown) of the primary system board 1104.

FIG. 12 depicts an exploded perspective view of an electronic device 1200 having a second riser cage assembly 900 of FIG. 9. In some examples, the electronic device 1200 may be a computer (e.g., server, storage device, etc.), networking device (e.g., transceiver, wireless access point, router, switch, etc.), or the like. In the example of FIG. 12, the electronic device 1200 is a server. In some examples, the electronic device 1200 includes a chassis 1202 and electronic components such as a primary system board 1204 (e.g., a motherboard), and the second riser cage assembly 900.

The chassis 1202 includes a plurality of passageways 1280 defined by brackets 1282 coupled to a base 1284 of the chassis 1202. For example, the chassis 1202 includes three passageways 1280, a first passageway 1280-1, a second passageway 1180-2, and a third passageway 1180-3, where each passageway is configured to receive the second riser cage assembly 900, and another second riser cage assembly 900-2, and yet another second riser cage assembly 900-3. The primary system board 1204 may be a printed circuit board of the electronic device 1200 having electrical circuitry integrated therein, such as conductive strips disposed on or in dielectric sheets, and to which one or more integrated circuits (IC), one or more input/outputs ports, power ports, electronic components, or the like are attached. In some examples, the primary system board 1204 includes a main electrical connector 1206.

In some examples, the second riser cage assembly 900 is disposed in the first passageway 1280-1 of the chassis 1202. In such examples, when the second riser cage assembly 900 is disposed in the first passageway 1208-1, the second electrical connector 574 (see, FIG. 5) of the riser card 508 is interchangeably detachably coupled to the main electrical connector 1206 of the primary system board 1204 to establish an electrical connection between the primary system board 1204 and the first expansion card 975-1 through the riser card 508, thereby allowing addition of the first expansion card 975-1 to the electronic device 1200 to satisfy/expand further requirements or functionality of the electronic device 1200. Further, in some examples, the first fixture 244 and the one or more third fixtures 754 of the second riser cage assembly 900 is coupled to the chassis 1220 (e.g., brackets 1282 and base 1284 of the chassis 1202, for example) so as to enable the second riser cage assembly 900 to be installed to the electronic device 1200. In the example of FIG. 12, the other second riser cage assembly 900-2 is shown to be pre-disposed in a second slot 1280-2 such that a riser card (not shown) of the second riser cage assembly 900-2 is connected to a second main connector (not shown) of the primary system board 1204. Similarly, yet another second riser cage assembly 900-3 is shown to be pre-disposed in a third slot 1280-3 such that a riser card (not shown) of the yet other second riser cage assembly 900-3 is connected to a second main connector (not shown) of the primary system board 1204.

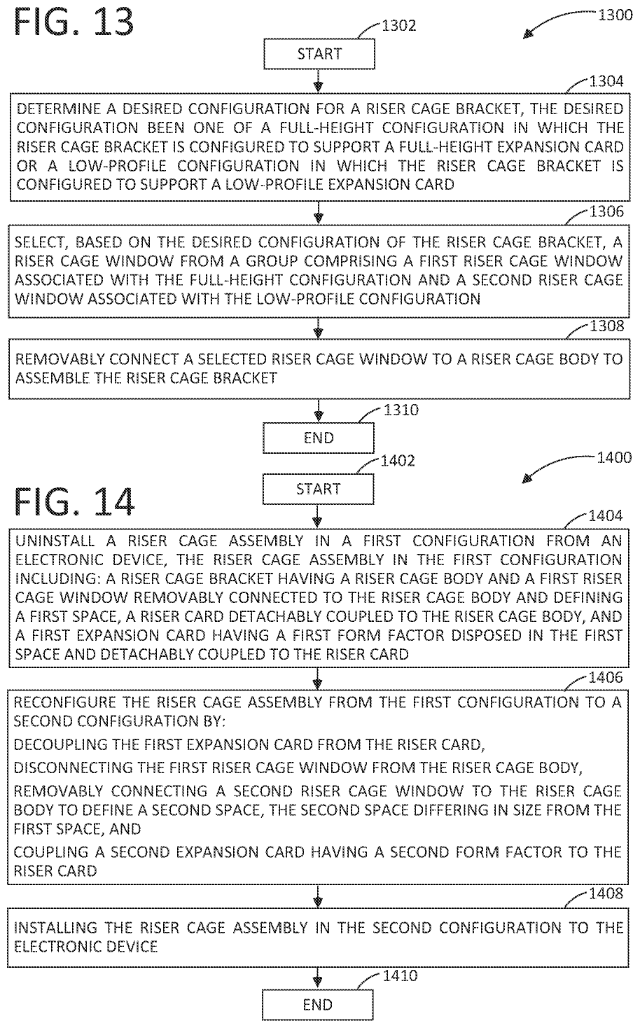

FIG. 13 depicts a flowchart showing a method 1300 of assembling a riser cage bracket. It may be noted herein that the method 1300 is described in conjunction with FIGS. 1A-1C and 2-12 for example. The method 1300 starts at block 1302 and continues to block 1304.

At block 1304, the method 1300 includes determining a desired configuration for a riser cage bracket, the desired configuration been one of a full-height configuration in which the riser cage bracket is configured to support a full-height expansion card or a low-profile configuration in which the riser cage bracket is configured to support a low-profile expansion card. The method 1300 continues to block 1306.

At block 1306, the method 1300 includes selecting, based on the desired configuration of the riser cage bracket, a riser cage window from a group including a first riser cage window associated with the full-height configuration and a second riser cage window associated with the low-profile configuration. In some examples, when the first riser cage window is selected to assemble the riser cage bracket, a first space is defined between the riser cage body and the first riser cage window to receive the full-height expansion card detachably coupled to the riser cage bracket. However, when the second riser cage window is selected to assemble the riser cage bracket, a second space is defined between the riser cage body and the second riser cage window to receive the low-profile expansion card detachably coupled to the riser cage bracket. The method 1300 continues to block 1308.

At block 1308, the method 1300 further includes removably connecting a selected riser cage window to a riser cage body to assemble the riser cage bracket. In some examples, removably connecting the selected riser cage window to the riser cage body includes disposing a length dimension of the selected riser cage window perpendicular to a length dimension of the riser cage body and engaging one or more fasteners with the selected riser cage window and with a coupling portion of the riser cage body to removably connect the selected riser cage window to the riser cage body.

In some examples, the method 1300 further includes coupling a riser card to the riser cage body, where the riser card is configured to be detachably coupled to an electronic device and to be interchangeably detachably coupled to the full-height expansion card and the low-profile expansion card. The method 1300 further includes detachably coupling one of the full-height expansion card or the low-profile expansion card to a first electrical connector of the riser card. Further, the method includes disposing the riser cage bracket in the electronic device such that a second electrical connector of the riser card is detachably coupled to a primary system board of the electronic device to establish an electrical connection between the primary system board and one of the full-height expansion card or the low-profile expansion card through the riser card.

In some examples, when the desired configuration is the full-height configuration, the selecting includes selecting the first riser cage window, and the removably connecting includes removably connecting the first riser cage window to the riser cage body. In such examples, the method 1300 further includes inserting the full-height expansion card into a first space defined between the riser cage body and the first riser cage window and detachably couple the full-height expansion card to the riser cage bracket. Similarly, when the desired configuration is the low-profile configuration, the selecting includes selecting the second riser cage window, and the removably connecting includes removably connecting the second riser cage window to the riser cage body. In such examples, the method 1300 further includes inserting the low-profile expansion card into a second space defined between the riser cage body and the second riser cage window and detachably couple the low-profile expansion card to the riser cage bracket. In one or more examples, the riser card is a peripheral component interconnect express (PCI-e) card, and wherein each of the full-height expansion card and the low-profile expansion card is a PCI-e expansion card. The method 1300 ends at block 1310.

FIG. 14 depicts a flowchart showing a method 1400 of uninstalling a riser cage assembly in a first configuration from an electronic device, reconfiguring the riser cage assembly from the first configuration to a second configuration, and installing the riser cage assembly in the second configuration to the electronic device. It may be noted herein that the method 1400 is described in conjunction with FIGS. 1A-1C and 2-12 for example. The method 1400 starts at block 1402 and continues to block 1404.

At block 1404, the method 1400 includes uninstalling a riser cage assembly in a first configuration from an electronic device. In some examples, the riser cage assembly in the first configuration includes: i) a riser cage bracket having a riser cage body and a first riser cage window removably connected to the riser cage body and defining a first space; ii) a riser card coupled to the riser cage body; and iii) a first expansion card having a first form factor disposed in the first space and detachably coupled to the riser card. The method 1400 continues to block 1406.

At block 1406, the method 1400 includes reconfiguring the riser cage assembly from the first configuration to a second configuration. In some examples, reconfiguring the riser cage assembly includes: i) decoupling the first expansion card from the riser card, ii) disconnecting the first riser cage window from the riser cage body, iii) removably connecting a second riser cage window to the riser cage body to define a second space, the second space differing in size from the first space, and iv) coupling a second expansion card having a second form factor to the riser card. In some examples, removably connecting the second riser cage window to the riser cage body to define the second space includes: a) disposing a length dimension of the second riser cage window perpendicular to a length dimension of the riser cage body, and b) engaging one or more fasteners with the second riser cage window and with a coupling portion of the riser cage body to removably connect the second riser cage window to the riser cage body. The method 1400 continues to block 1408.

At block 1408, the method 1400 includes installing the riser cage assembly in the second configuration to the electronic device. The method 1400 ends at block 1410.

Since a new riser cage bracket may be easily assembled by interchangeably and removably connecting one of a multiple types of riser cage windows onto a common riser cage body to form the new riser cage bracket that is compatible with a particular type of expansion card, the new riser cage bracket provides flexibility, serviceability, and benefit from supply chain in terms of reducing number of ready-made riser cage brackets needed in the inventory. Further, the new riser cage bracket is inexpensive to assemble, maintain, and replace, since the riser cage body and a riser board of the pre-installed riser cage bracket are retained, and only the riser cage window that is incompatible with the expansion card is replaced with the riser cage window that is compatible with the expansion card to assemble the new riser cage bracket.

In the foregoing description, numerous details are set forth to provide an understanding of the subject matter disclosed herein. However, implementation may be practiced without some or all of these details. Other implementations may include modifications, combinations, and variations from the details discussed above. It is intended that the following claims cover such modifications and variations.

What is claimed is:

1. A system for assembling a riser cage bracket, comprising:
a riser cage body;
a first riser cage window; and
a second riser cage window, wherein the first and second riser cage windows are configured to be interchangeably and removably connectable to the riser cage body to assemble the riser cage bracket;
wherein the first riser cage window is configured to, when connected to the riser cage body, define a first space between the riser cage body and the first riser cage window to receive a full-height expansion card detachably coupled to the riser cage bracket; and
wherein the second riser cage window is configured to, when connected to the riser cage body, define a second space between the riser cage body and the second riser cage window to receive a low-profile expansion card detachably coupled to the riser cage bracket.

2. The system of claim 1, further comprising a riser card configured to be coupled to the riser cage body, wherein the riser card comprises a first electrical connector i) configured to be detachably coupled to the full-height expansion card when the first riser cage window is connected to the riser cage body and ii) configured to be detachably coupled to the low-profile expansion card when the second riser cage window is connected to the riser cage body, and wherein the riser card further comprises a second electrical connector configured to be detachably coupled to a primary system board of an electronic device to establish an electrical connection between the primary system board and the full-height expansion card or the low-profile expansion card through the riser card.

3. The system of claim 2, wherein the riser card is a peripheral component interconnect express (PCI-e) card, and wherein each of the full-height expansion card and the low-profile expansion card is a PCI-e expansion card.

4. The system of claim 1, wherein a length dimension of the first riser cage window extends perpendicular to a length dimension of the riser cage body when the first riser cage window is connected to the riser cage body, and wherein a length dimension of the second riser cage window extends perpendicular to the length dimension of the riser cage body when the second riser cage window is connected to the riser cage body.

5. The system of claim 1, wherein the riser cage body comprises a coupling portion configured to interchangeably connect with the first riser cage window and the second riser cage window.

6. The system of claim 5, further comprising one or more fasteners configured to, interchangeably:
engage with the first riser cage window and with the coupling portion to removably connect the first riser cage window to the riser cage body; and
engage with the second riser cage window and with the coupling portion to removably connect the first riser cage window to the riser cage body.

7. The system of claim 1, wherein each of the first riser cage window and the second riser cage window have different lengths along their respective longitudinal dimensions.

8. The system of claim 1, wherein each of the first space and the second space has dimensions defined by the riser cage body and a corresponding riser cage window among the first riser cage window and the second riser cage window, and wherein each of the first space and the second space has an equal length, an equal width, and a different height.

9. A riser cage bracket comprising:
a riser cage body; and
a riser cage window removably connected to the riser cage body to allow the riser cage bracket to support one of a full-height expansion card or a low-profile expansion card.

10. The riser cage bracket of claim 9, wherein a length dimension of the riser cage window extends perpendicular to a length dimension of the riser cage body when the riser cage window is connected to the riser cage body.

11. The riser cage bracket of claim 9, wherein the riser cage body comprises a coupling portion configured to removably connect the riser cage body with the riser cage window, and wherein the riser cage bracket further comprises one or more fasteners configured to engage with the riser cage window and with the coupling portion to removably connect the riser cage window to the riser cage body.

12. A method comprising:
determining a desired configuration for a riser cage bracket, the desired configuration been one of a full-height configuration in which the riser cage bracket is configured to support a full-height expansion card or a low-profile configuration in which the riser cage bracket is configured to support a low-profile expansion card;
selecting, based on the desired configuration of the riser cage bracket, a riser cage window from a group comprising a first riser cage window associated with the full-height configuration and a second riser cage window associated with the low-profile configuration; and
removably connecting a selected riser cage window to a riser cage body to assemble the riser cage bracket.

13. The method of claim 12,
wherein, when the first riser cage window is selected to assemble the riser cage bracket, a first space is defined between the riser cage body and the first riser cage window to receive the full-height expansion card detachably coupled to the riser cage bracket, and
wherein, when the second riser cage window is selected to assemble the riser cage bracket, a second space is defined between the riser cage body and the second riser cage window to receive the low-profile expansion card detachably coupled to the riser cage bracket.

14. The method of claim 12, wherein removably connecting the selected riser cage window to the riser cage body comprises:
disposing a length dimension of the selected riser cage window perpendicular to a length dimension of the riser cage body; and
engaging one or more fasteners with the selected riser cage window and with a coupling portion of the riser cage body to removably connect the selected riser cage window to the riser cage body.

15. The method of claim 12, further comprising:
coupling a riser card to the riser cage body, the riser card configured to be detachably coupled to an electronic device and to be interchangeably detachably coupled to the full-height expansion card and the low-profile expansion card;
detachably coupling one of the full-height expansion card or the low-profile expansion card to a first electrical connector of the riser card; and
disposing the riser cage bracket in the electronic device such that a second electrical connector of the riser card is detachably coupled to a primary system board of the electronic device to establish an electrical connection between the primary system board and one of the full-height expansion card or the low-profile expansion card through the riser card.

16. The method of claim 15, wherein the riser card is a peripheral component interconnect express (PCI-e) card, and wherein each of the full-height expansion card and the low-profile expansion card is a PCI-e expansion card.

17. The method of claim 12,
wherein the desired configuration is the full-height configuration, the selecting comprises selecting the first riser cage window, and the removably connecting comprises removably connecting the first riser cage window to the riser cage body; and
the method further comprises inserting the full-height expansion card into a first space defined between the riser cage body and the first riser cage window and detachably couple the full-height expansion card to the riser cage bracket.

18. The method of claim 12,
wherein the desired configuration is the low-profile configuration, the selecting comprises selecting the second riser cage window, and the removably connecting comprises removably connecting the second riser cage window to the riser cage body; and
the method further comprises inserting the low-profile expansion card into a second space defined between the riser cage body and the second riser cage window and detachably couple the low-profile expansion card to the riser cage bracket.

19. A method comprising:
uninstalling a riser cage assembly in a first configuration from an electronic device, the riser cage assembly in the first configuration comprising: a riser cage bracket having a riser cage body and a first riser cage window removably connected to the riser cage body and defining a first space; a riser card coupled to the riser cage body; and a first expansion card having a first form factor disposed in the first space and detachably coupled to the riser card;
reconfiguring the riser cage assembly from the first configuration to a second configuration by:
decoupling the first expansion card from the riser card;
disconnecting the first riser cage window from the riser cage body;
removably connecting a second riser cage window to the riser cage body to define a second space, the second space differing in size from the first space; and
coupling a second expansion card having a second form factor to the riser card; and
installing the riser cage assembly in the second configuration to the electronic device.

20. The method of claim 19, wherein removably connecting the second riser cage window to the riser cage body to define the second space comprises:
disposing a length dimension of the second riser cage window perpendicular to a length dimension of the riser cage body; and
engaging one or more fasteners with the second riser cage window and with a coupling portion of the riser cage body to removably connect the second riser cage window to the riser cage body.
